(19) United States
(12) Patent Application Publication
(10) Pub. No.: US 2026/0266876 A1
(43) Pub. Date: Sep. 10, 2026

(54) METHOD OF MANUFACTURING A PROBE HEAD MANUFACTURED BY STACKING PROBE PINS AND COMBINED WITH A SPATIAL CONVERTER AND AN ANISOTROPIC CONDUCTIVE FILM

(71) Applicant: NANO-X CO., LTD, Suwon-si (KR)

(72) Inventors: Doo Jin PARK, Yongin-si (KR); Pil Kuk JANG, Seoul (KR)

(21) Appl. No.: 19/663,017

(22) Filed: Apr. 29, 2026

Related U.S. Application Data
(63) Continuation of application No. PCT/KR2024/016824, filed on Oct. 30, 2024.

(30) Foreign Application Priority Data
Oct. 31, 2023 (KR) 10-2023-0148385

(51) Int. Cl. G01R 3/00; G01R 31/28; G03F 7/00

(52) U.S. Cl. CPC G01R 3/00; G01R 31/2886; G03F 7/0035

(57) ABSTRACT

Provided is a method for manufacturing a probe head, and more particularly, to a method for manufacturing a probe head in which the pitch between pins can be finely adjusted by stacking probe pins and the length and shape of the probe pins can be freely formed.

### CROSS-REFERENCE TO RELATED APPLICATION(S)

This application is a continuation application of PCT International Application No. PCT/KR2024/016824, filed on October 30, 2024, and claims priority to Korean Application No. 10-2023-0148385, filed on October 31, 2023, in the Ministry of Intellectual Property (MOIP) of the Republic of Korea, the entire contents of which are incorporated herein by reference.

### FIELD OF THE INVENTION

The present invention relates to a method for manufacturing a probe head, and more particularly, to a method for manufacturing a probe head in which the pitch between pins can be finely adjusted by stacking probe pins, the length and shape of the probe pins can be freely formed, and a spatial converter is connected by an anisotropic conductive film.

### BACKGROUND ART

After an electric device is manufactured, it is necessary to inspect its electrical characteristics by connecting inspection equipment to the electric device. Although it is possible to inspect by simply connecting inspection equipment to electrodes of the electric device by a person, it consumes considerable time and cost for a person to inspect each one in the process of producing a large number of products. Therefore, probe heads that are mechanically brought into contact with electric devices to provide electrical connection have been developed and used.

With the development of technology, as the integration degree of electric circuits is improved and the size of electric devices is reduced day by day so that the size and spacing of electrodes are also reduced to units of micrometers or less, there is a need for corresponding probe heads to also be reduced to a fine size.

However, since the probe pins of a probe head manufactured by the conventional technology are manufactured in a manner in which the probe pins are grown in a longitudinal direction, there is a problem in that it is difficult to freely manufacture the shape of the probe pins, and it is difficult to finely form a pitch, which is a spacing between the probe pins.

### DESCRIPTION OF THE INVENTION

### Technical Problem

The technical objective of the present invention is to provide a method for manufacturing a probe head having a fine pitch between probe pins.

Another technical objective of the present invention is to provide a probe head capable of inspecting multiple devices simultaneously.

Another technical objective of the present invention is to provide a method for manufacturing a probe head in which the shape of the probe pins can be freely formed.

Another technical objective of the present invention is to easily couple a probe head and a spatial converter with an anisotropic conductive film.

### Technical Solution

To achieve the above objectives, the present invention provides a method for manufacturing a probe head comprising:

a first elastic layer forming step of forming a first elastic layer;

a first pin forming step of forming one or more first probe pins on the upper surface of the first elastic layer; and

a second elastic layer stacking step of forming a second elastic layer over the first elastic layer on which the first probe pins are formed.

The method may further comprise a second pin forming step of forming one or more second probe pins on the upper surface of the second elastic layer.

The method may further comprise a layer stacking step in which the first pin forming step and the second elastic layer stacking step are repeated a predetermined number of times to stack layers composed of pin layers and elastic layers.

The first pin forming step may comprise forming the first probe pins in a manner such that they are arranged in parallel on a plane on the upper surface of the first elastic layer.

In addition, the first pin forming step may comprise forming the first probe pins such that a second spacing between the other ends is greater than a first spacing between one ends of the first probe pins, and the one ends and the other ends are connected in shape.

Further, in claim 1, the first pin forming step may comprise forming the one end and the other end of each first probe pin in a rod shape and providing a shock-absorbing structure in the center thereof to absorb impact.

The first elastic layer forming step and the second elastic layer stacking step may comprise forming an elastic sacrificial layer at both ends of the first probe pins.

Further, the method may comprise a first photoresist forming step of forming a first photoresist including a first sacrificial layer at both ends of the first probe pins before the first elastic layer forming step, and a second photoresist forming step of forming a second photoresist including a second sacrificial layer at both ends of the first probe pins after the second elastic layer stacking step.

The method may further comprise a sacrificial layer removal step of removing the elastic sacrificial layer, the first sacrificial layer, and the second sacrificial layer.

The first elastic layer forming step may be performed on the upper surface of a substrate, and a cavity forming step of forming one or more cavities on the lower surface of the substrate may be further comprised before or after the first elastic layer forming step.

The method may further comprise, after the sacrificial layer removal step, a spatial converter coupling step of coupling the probe head and a spatial converter, wherein the spatial converter includes, on one surface of the spatial converter, a plurality of spatial converter electrodes connected to the other ends of the first probe pins.

Further, the spatial converter may be provided with an anisotropic conductive film on a surface where the other ends of the first probe pins and the spatial converter are in contact, such that the first probe pins and the plurality of spatial converter electrodes provided in the spatial converter are electrically connected.

### Advantageous Effects

According to the present invention, it is possible to manufacture a probe head having a fine pitch between probe pins.

It is also possible to provide a probe head capable of inspecting multiple devices simultaneously.

Furthermore, the present invention provides a method for manufacturing a probe head in which the shape of the probe pins can be freely formed.

Additionally, the probe head and the spatial converter can be easily coupled by an anisotropic conductive film, and insulation can be secured.

### BRIEF DESCRIPTION OF THE DRAWINGS

FIG. 1 is a view illustrating a probe head according to a method for manufacturing a probe head according to an embodiment of the present invention.

FIG. 2 is a perspective view illustrating a probe head according to an embodiment of the present invention.

FIG. 3 is a flowchart illustrating a method for manufacturing a probe head according to an embodiment of the present invention.

FIG. 4 is a perspective view illustrating a probe head according to an embodiment of the present invention.

FIG. 5 is a view illustrating the formation of a substrate sacrificial layer according to an embodiment of the present invention.

FIG. 6 is a view illustrating a first photoresist forming step according to an embodiment of the present invention.

FIG. 7 is a view illustrating the formation of a first sacrificial layer in the first photoresist according to an embodiment of the present invention.

FIGS. 8 to 13 are views illustrating the first elastic layer forming step in which an elastic sacrificial layer is formed according to an embodiment of the present invention.

FIG. 14 is a view illustrating the first pin forming step according to an embodiment of the present invention.

FIG. 15 is a view illustrating the second elastic layer forming step according to an embodiment of the present invention.

FIG. 16 is a view illustrating multiple layers being stacked through the layer stacking step according to an embodiment of the present invention.

FIG. 17 is a view illustrating a second photoresist forming step according to an embodiment of the present invention.

FIG. 18 is a view illustrating the sacrificial layer removal step according to an embodiment of the present invention.

FIG. 19 is a view illustrating the formation of the probe pins on a plane according to an embodiment of the present invention.

FIG. 20 is a view illustrating a probe pin including a shock-absorbing structure according to an embodiment of the present invention.

FIG. 21 is a view illustrating a cavity forming step according to an embodiment of the present invention.

FIG. 22 is a perspective view looking up from the bottom of a substrate in which a cavity forming step has been performed according to an embodiment of the present invention.

FIG. 23 is a perspective view illustrating a state in which a spatial converter is coupled with a probe head according to an embodiment of the present invention.

FIG. 24 is a view illustrating a sectional view of a state in which a spatial converter is coupled with a probe head according to an embodiment of the present invention.

FIG. 25 is a view illustrating a state in which a spatial converter coupling step is started according to an embodiment of the present invention.

FIG. 26 is a view illustrating a state in which a spatial converter coupling step is performed according to an embodiment of the present invention.

### BEST MODE FOR CARRYING OUT THE INVENTION

Provided is a method for manufacturing a probe head, comprising a first elastic layer forming step of forming a first elastic layer, a first pin forming step of forming one or more first probe pins on an upper surface of the first elastic layer, and a second elastic layer stacking step of forming a second elastic layer over the first elastic layer on which the first probe pins are formed, wherein the probe head is manufactured.

### MODE FOR CARRYING OUT THE INVENTION

Hereinafter, exemplary embodiments of the present invention will be described in detail with reference to the accompanying drawings so that those skilled in the art can readily carry out the invention. However, the present invention may be embodied in various different forms and is not limited to the embodiments disclosed herein. Parts not related to the invention are omitted from the drawings for clarity, and the same or similar reference numerals in the drawings denote the same or similar elements.

The objects and effects of the present invention will be naturally understood or more clearly appreciated from the following description. However, the objectives and effects of the invention are not limited to the following descriptions.

The objects, features, and advantages of the present invention will become more apparent from the following detailed description. In addition, in describing the present invention, when it is determined that a detailed description of known technology related to the present invention may unnecessarily obscure the gist of the present invention, the detailed description thereof will be omitted. Hereinafter, embodiments according to the present invention will be described in detail with reference to the accompanying drawings.

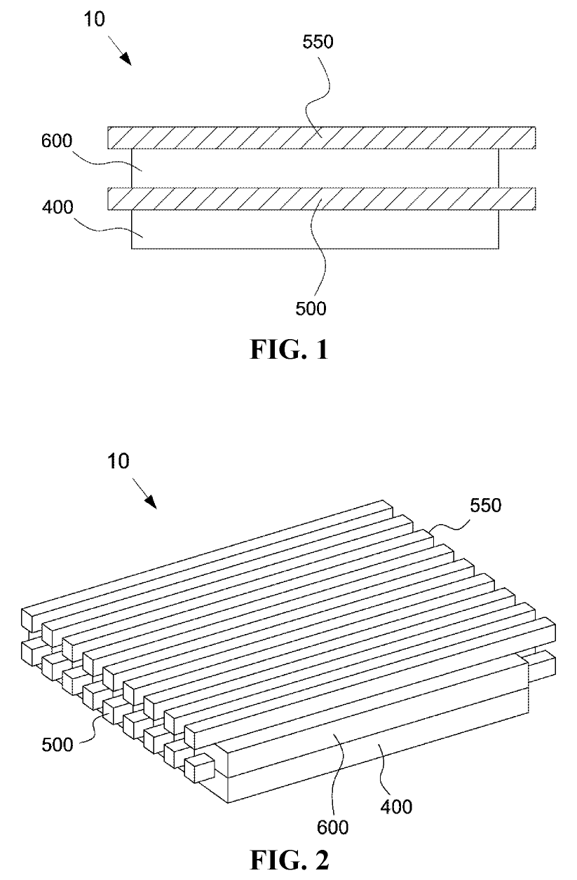

FIG. 1 is a view illustrating a probe head according to a method for manufacturing a probe head according to an embodiment of the present invention.

FIG. 2 is a perspective view illustrating a probe head according to an embodiment of the present invention.

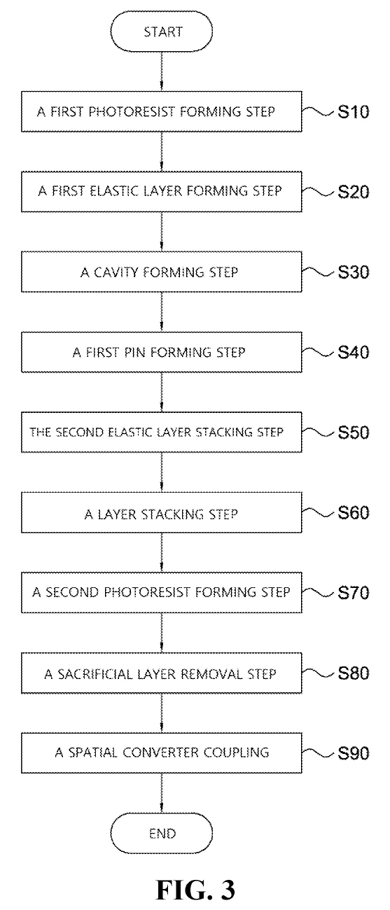

FIG. 3 is a flowchart illustrating a method for manufacturing a probe head according to an embodiment of the present invention.

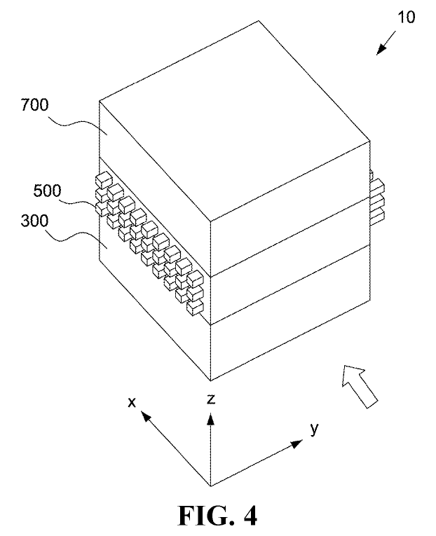

FIG. 4 is a perspective view illustrating a probe head according to an embodiment of the present invention.

Referring to FIGS. 1 to 4, a method for manufacturing a probe head (10) according to an embodiment of the present invention includes: a first photoresist forming step (S10), a first elastic layer forming step (S20), a cavity forming step (S30), a first pin forming step (S40), a second elastic layer stacking step (S50), a layer stacking step (S60), a second photoresist forming step (S70), and a sacrificial layer removal step (S80). Each of these steps will be described in detail below.

FIG. 4 is a perspective view illustrating a probe head (10) according to an embodiment of the present invention. Referring to FIG. 4, the probe head (10) includes a plurality of probe pins, and the upper and lower sides of the plurality of probe pins may include a first photoresist (300) and a second photoresist (700). The longitudinal direction of the probe pins is defined as the y-axis direction. The pin layers are stacked in the vertical direction of the substrate (100), which is defined as the z-axis direction. The direction in which the probe pins are arranged in the pin layer is defined as the x-axis direction.

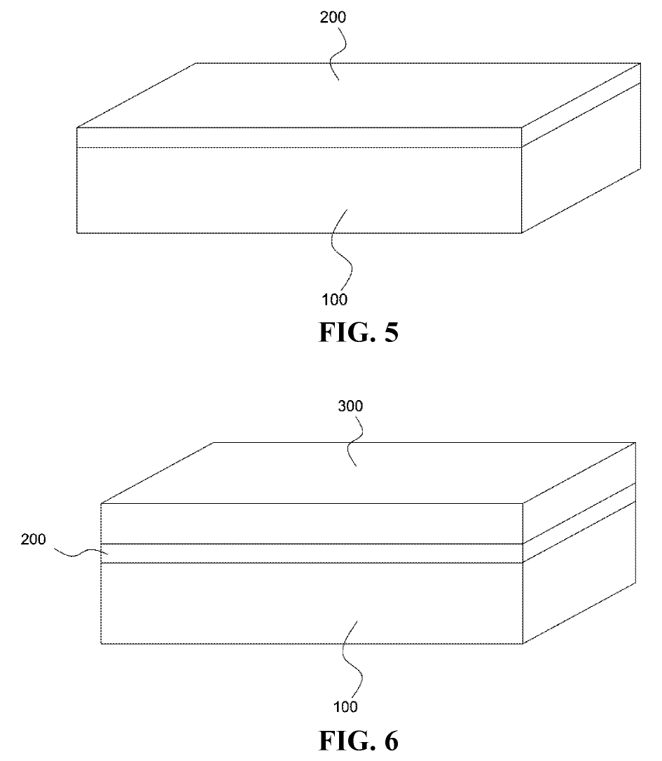

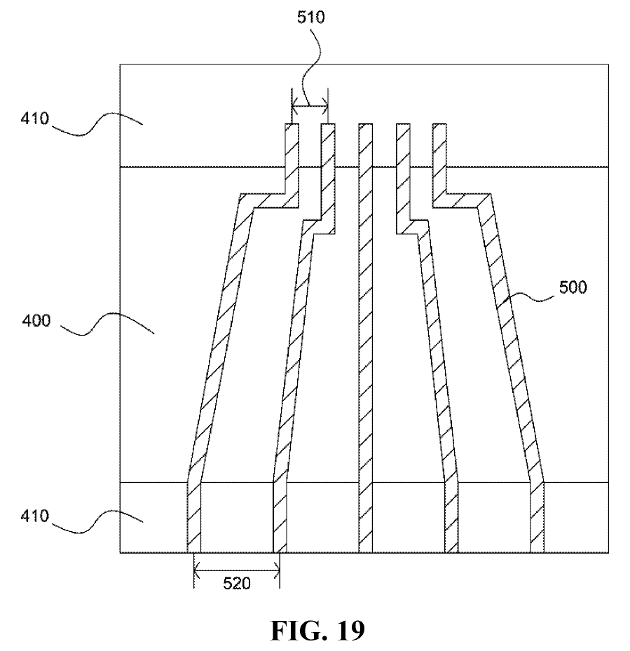

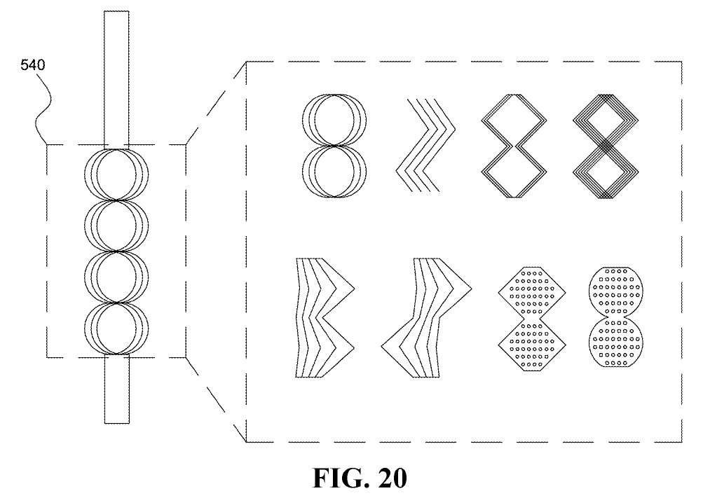

FIGS. 5 to 18 are sectional views viewed from the direction of the arrows in FIG. 3, illustrating the stacking process. FIGS. 19 and 20 are views from the z-axis direction, i.e., top-down views.

The substrate sacrificial layer forming step is a step of forming a substrate sacrificial layer (200) on a substrate (100). Referring to FIG. 5, it can be seen that the substrate sacrificial layer (200) is formed on the substrate (100). The substrate (100) may be formed of various types of wafers, and the substrate sacrificial layer (200) is a configuration that is ultimately removed in order to separate the probe head (10) from the substrate (100) as a sacrificial layer, and thus may be formed of various materials used as sacrificial layers, but in an embodiment of the present invention, description will be made on the basis that it is formed of aluminum.

When the substrate sacrificial layer (200) is provided in this manner, the probe head (10) may ultimately be separated from the substrate (100) through the sacrificial layer removal step (S80), and components for configuring the probe head (10) may be stacked thereon based on the substrate sacrificial layer (200).

Meanwhile, the above-described substrate sacrificial layer forming step may be performed before the first photoresist forming step, and such substrate sacrificial layer may be removed using a cavity formed in the substrate through the cavity forming step (S30), which will be described later.

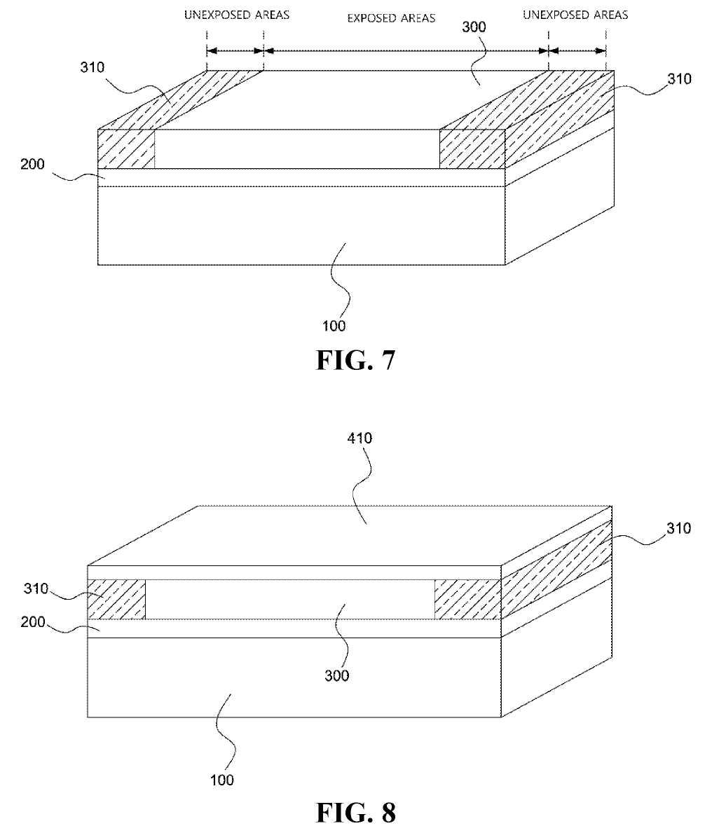

The first photoresist forming step (S10) is performed between the substrate sacrificial layer forming step and the first elastic layer forming step (S20), and is a step of coating the first photoresist (300) on the substrate sacrificial layer (200). The first photoresist forming step (S10) includes a step of coating photoresist on the substrate sacrificial layer (200) and a step of forming a first sacrificial layer (310). FIG. 6 is a view illustrating a step of coating the first photoresist (300) on the substrate sacrificial layer (200), and FIG. 7 shows an exposed region at the center portion of the first photoresist (300) and unexposed regions at both ends. After coating the first photoresist (300), by exposing the exposed region and curing the first photoresist (300), the first photoresist (300) composed only of the first photoresist (300) in FIG. 6 is formed separately into the first photoresist (300) at the center portion and the first sacrificial layers (310) at both side surfaces as shown in FIG. 7.

At this time, the first photoresist (300) may be formed by repeating the coating step at least once so that the first photoresist (300) is coated in multiple layers to form a desired thickness, or a method of thickly coating one photoresist may be used. However, the method of coating in multiple layers is advantageous because the thickness of the first photoresist (300) can be efficiently formed in various ways.

Meanwhile, various kinds of photoresist may be used, but in an embodiment of the present invention, description will be made on the basis of using an epoxy-based negative photoresist formed of SU-8, and when a positive photoresist is used, the same result can be obtained by reversing the above-described exposed region and unexposed region to perform the step.

When the first photoresist (300) is provided through the first photoresist forming step (S10) in this manner, the first probe pins (500) to be stacked later may be protected, the thickness of the first photoresist (300) may be efficiently adjusted, and finally, by removing the unexposed portions, both ends of the first probe pins (500) may be caused to protrude.

The first elastic layer forming step (S20) is a step of depositing an elastic layer (400) on a substrate (100).

The first elastic layer forming step (S20) is performed by being divided into an elastic sacrificial layer (410) preparation step and a deposition step, and the elastic sacrificial layer (410) preparation step is a step of providing the elastic sacrificial layer (410), which serves as a basis for performing the elastic sacrificial layer forming step later.

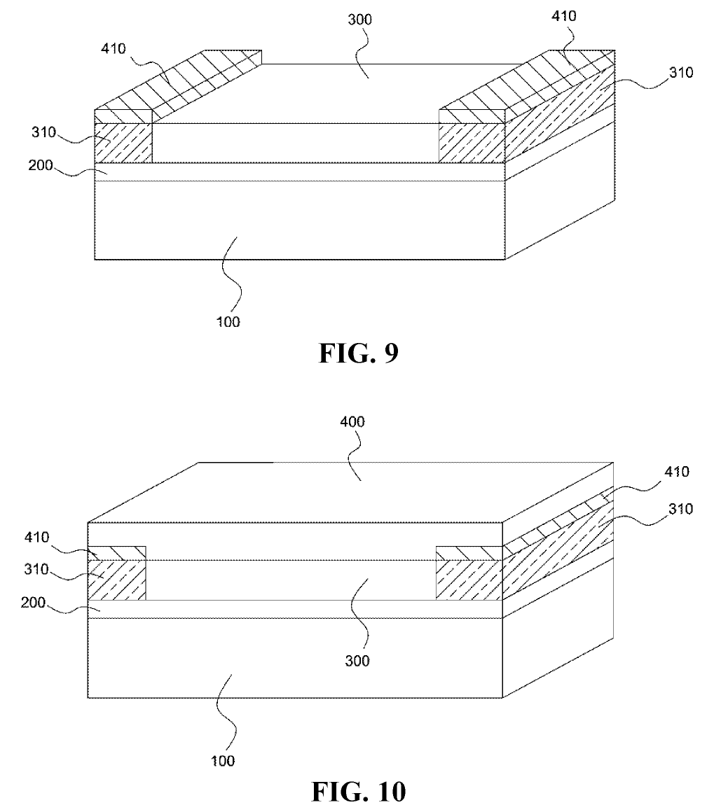

Referring to FIGS. 8 and 9 illustrating the elastic sacrificial layer (410) preparation step, FIG. 8 is a view illustrating that the elastic sacrificial layer (410) is deposited, and FIG. 9 illustrates that only the elastic sacrificial layer (410) in the unexposed region remains by etching the elastic sacrificial layer (410) in the above-described exposed region.

Thereafter, the deposition step is performed to deposit the first elastic layer (400). FIG. 10 is a view illustrating a state in which the first elastic layer (400) is deposited, and referring thereto, when the first elastic layer (400) is deposited through the deposition step, the first elastic layer (400) covers the elastic sacrificial layer (410) and the first photoresist (300).

Meanwhile, in the first elastic layer forming step (S20), the first elastic layer (400) may be deposited on the substrate (100), or only the first elastic layer (400) may be provided alone, and when the substrate sacrificial layer forming step is performed before the first elastic layer forming step (S20), the first elastic layer (400) may be deposited on the substrate sacrificial layer (200), and when other steps are performed earlier, the first elastic layer (400) may also be deposited over the configuration provided on the substrate (100) after the corresponding step is performed.

The elastic sacrificial layer forming step is a step of forming one end of the first elastic layer (400) as a sacrificial layer. However, in the elastic sacrificial layer forming step, a sacrificial layer may be formed not only at one end of the first elastic layer (400) but also at the other end so that the elastic sacrificial layer (410) may be provided at both ends, and FIGS. 10 to 13 are prepared on the basis that a sacrificial layer is formed at both ends, and hereinafter, description will be made on the basis that a sacrificial layer is formed at both ends.

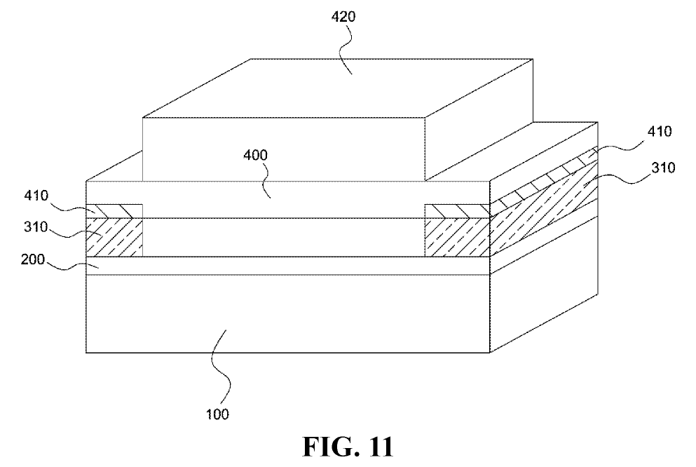

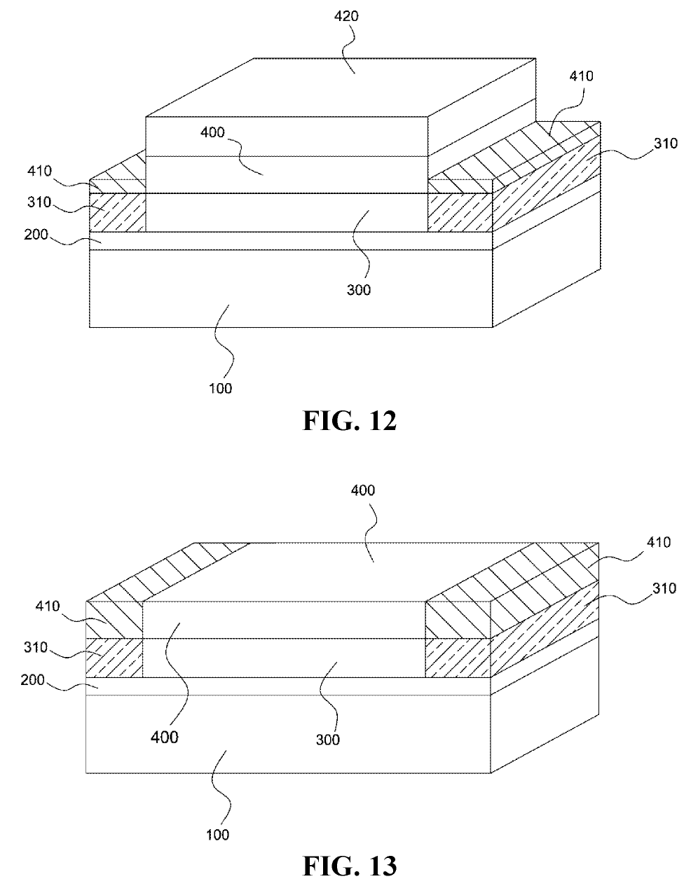

FIG. 10 is a view illustrating a state in which the first elastic layer forming step (S20) is completed, and FIGS. 11 to 13 are views illustrating that the elastic sacrificial layer forming step is sequentially performed. FIG. 11 illustrates that an elastic layer photoresist (420) is deposited on the exposed region of the first elastic layer (400). Thereafter, when dry etching is performed, the elastic layer photoresist (420) and the first elastic layer (400) are etched together, and when all of the first elastic layer (400) in the unexposed region is etched so that the elastic sacrificial layer (410) is exposed, etch stop occurs to form a shape as shown in FIG. 12. Next, after depositing the elastic sacrificial layer (410) until the height of the first elastic layer (400) and the elastic sacrificial layer (410) becomes the same, lift-off is performed to remove the elastic layer photoresist (420), thereby forming a shape in which the heights of the first elastic layer (400) and the elastic sacrificial layer (410) become the same as shown in FIG. 13.

Meanwhile, the elastic sacrificial layer (410) may be formed of various materials or substances capable of forming a sacrificial layer, but in an embodiment of the present invention, description will be made on the basis that it is formed of aluminum, and when the elastic sacrificial layer (410) is formed in the unexposed region in this manner, both ends of the probe pins may finally be caused to protrude by removing the unexposed portion.

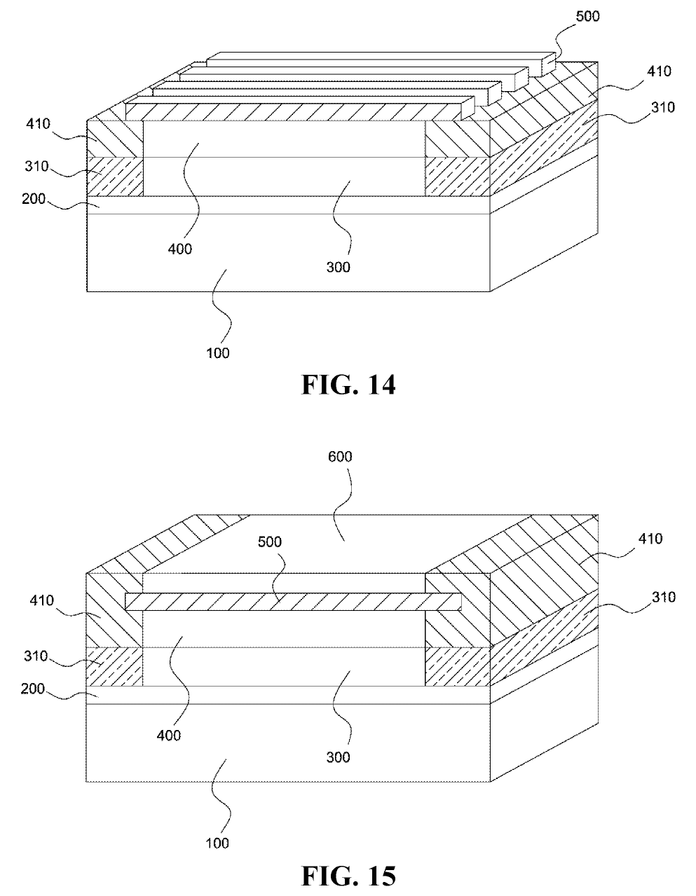

The first pin forming step (S40) is a step of forming a pin layer by depositing a plurality of first probe pins (500) on the plane of the upper surface of the first elastic layer (400). Referring to FIG. 14, it can be seen that a plurality of pins are formed on the plane of the upper surface of the first elastic layer (400), and more specifically, a plurality of first probe pins (500) are arranged in parallel in the y-axis direction with the x-axis direction as the longitudinal direction to form one layer, thereby becoming a probe pin layer.

The first pin forming step (S40), in which the probe pins are arranged, may form the pin layer composed of the plurality of first probe pins (500) through an etching process or a lift-off process.

Meanwhile, referring to FIGS. 19 and 20, the shape of the first probe pin (500) may have various patterns such as being bent or curved when viewed from top to bottom on the z-axis, and since the plurality of first probe pins (500) are deposited in a manner of being laid down in the longitudinal direction on a plane, the shape of the first probe pins (500) may be easily modified. In addition, since the pins are formed on a plane, the spacing between the pins may also be freely adjusted, and it is easy to implement a fine pitch.

At this time, FIG. 19 shows an example in which the shape of the pins may be configured in various ways in the first pin forming step, and a probe head may be manufactured, wherein the second spacing (520), which is a spacing between the other ends of the first probe pins (500), is greater than the first spacing (510) between one ends of the first probe pins (500), and the first probe pins (500) are formed in a shape in which the one ends and the other ends are connected to each other.

At this time, one end and the other end of the first probe pin (500) may have a section formed partially in a straight line shape, and this is to absorb impact by receiving force in a vertical direction when vertically contacting inspection equipment or an inspection target, and impact may be absorbed by varying the structure between the one end and the other end.

At this time, referring to FIG. 19, the one end and the other end are diagonally connected in a manner similar to a cantilever structure, and through this, when force is received in a vertical direction, the force may be dispersed.

However, the present invention is not limited to the example of FIG. 19, and the one end and the other end of the first probe pins (500), which have various shapes and different spacings from each other, may be connected. In addition, when the spacing between the first probe pins (500) is formed to be narrow at one end and wide at the other end in this manner, even if a fine pitch is formed at one end in order to contact an inspection target, connection of the probe pins to inspection equipment or the like may be facilitated because the other end has a wide spacing.

In addition, referring to FIG. 20, the first probe pin (500) may be formed such that one end and the other end have a rod shape and the center portion has a shock-absorbing structure (540) for absorbing impact.

The shock-absorbing structure (540) is a structure for absorbing an impact received when the first probe pin (500) contacts an inspection target by utilizing various shapes, and since the first probe pin (500) is formed on a plane, structures of various shapes may be provided. Referring to FIG. 20, various shapes possible as the shock-absorbing structure (540) are exemplified, but the present invention is not limited thereto, and various shapes capable of efficiently absorbing impact may be formed in the first probe pin (500). FIG. 15 is a view illustrating a state in which the second elastic layer stacking step (S50) is performed on the pin layer according to an embodiment of the present invention.

The second elastic layer stacking step (S50) is a step of stacking the second elastic layer (600) by being repeated in the same manner as the first elastic layer forming step (S20) described above, and the first probe pin (500) is disposed on the first elastic layer and the second elastic layer is stacked thereon, such that the first elastic layer (400) and the second elastic layer (600) form one elastic layer surrounding the first probe pin (500).

When the second elastic layer (600) is provided in this manner, the first probe pin (500) may be surrounded so that the pin layer is not exposed to the outside, and the elastic layer surrounds the first probe pin (500) so that the first probe pin (500) may be protected and insulated from the outside, and when the first probe pin (500) surrounded by the elastic layer receives an external force, the force may be dispersed to prevent damage to the first probe pin (500).

However, referring to FIGS. 1 and 2, it may be seen that, after stacking the second elastic layer (600), a state in which a second pin forming step of forming one or more second probe pins (550) on the upper surface of the second elastic layer (600) is performed.

This represents a form in which the second probe pins (550) are formed and the step is terminated, unlike the layer stacking step (S60) to be described later, and if the second elastic layer stacking step (S50) is repeated after the second pin forming step, layers may be stacked in the same manner as in the layer stacking step (S60).

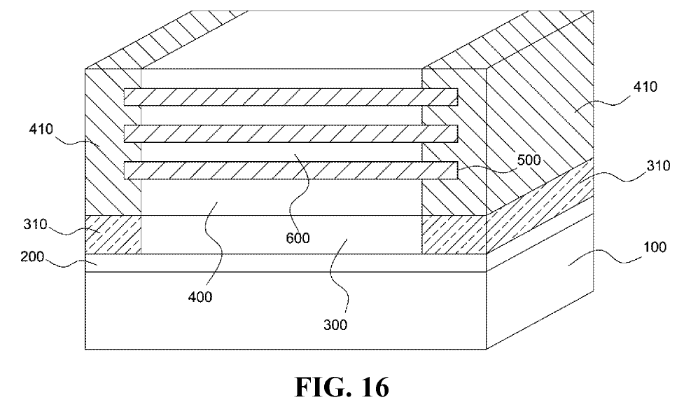

However, when the second probe pins (550) are formed in this manner, they may be utilized in various ways, such as placing a new layer on the second probe pins (550) or coupling attachable components thereto, and it is also possible to form the second probe pins (550) after the layer stacking step (S60) and terminate the step in a state in which probe pins are formed on multiple layers. FIG. 16 is a view illustrating a state in which multiple layers are stacked through the layer stacking step (S60) according to an embodiment of the present invention.

Referring to FIG. 16, an embodiment of the present invention may further include a layer stacking step (S60) of repeatedly performing the first pin forming step (S40) and the second elastic layer stacking step (S50) a predetermined number of times to repeatedly stack layers composed of pin layers and elastic layers. FIG. 16 illustrates a form in which, after the second elastic layer stacking step (S50), the first pin forming step (S40) and the second elastic layer stacking step (S50) are repeated twice, such that a total of two additional layers are stacked, thereby providing three layers including the previously formed one layer.

Meanwhile, looking at the arrangement of the probe pins provided in the probe head (10), if it is assumed that the number of pins arranged in parallel in the x-axis direction constitutes the number of rows, the total number of pin layers stacked in the z-axis direction by repeating the layer stacking step (S60) a predetermined number of times constitutes the number of columns.

That is, since the predetermined number of times of the layer stacking step (S60) determines the number of rows or columns of the probe head (10), it is determined in consideration of the number of rows or columns of the probe head (10) to be manufactured.

As described above, when the second elastic layer stacking step (S50) is performed after the first pin forming step (S40), the elastic layer surrounds the pins. At this time, when the pin layers are stacked in the z-axis direction through the first pin forming step (S40) and the second elastic layer stacking step (S50), the thickness of the second elastic layer (600) deposited between the pins determines the pitch between the pins, and the spacing between the pins may be adjusted by adjusting the thickness of the second elastic layer (600), thereby making it possible to form a fine pitch.

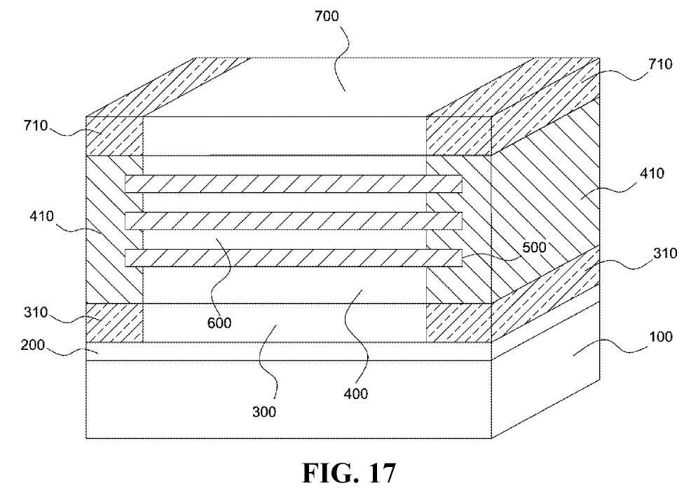

Meanwhile, referring to FIG. 17, when a plurality of pin layers are stacked as described above, a second photoresist forming step (S70) may be further included, and the second photoresist forming step (S70) is a step of coating the second photoresist (700) on the elastic layer. FIG. 17 is a view illustrating a state in which the second photoresist forming step (S70) is performed, and the second photoresist (700) and the second sacrificial layer (710) are stacked on the elastic layer.

The second photoresist forming step (S70) is formed through the same process as the above-described first photoresist forming step (S10), and the probe head (10) may be provided with both the first photoresist (300) and the second photoresist (700), may be provided with neither of them, or may be provided with only one of the first photoresist (300) and the second photoresist (700).

When the second photoresist (700) is provided by further including the second photoresist forming step (S70) in this manner, the probe pins may be protected from external impact, and when both the first photoresist (300) and the second photoresist (700) are provided, the first and second photoresists (700) are formed at both ends of the probe head (10) in the z-axis direction, thereby efficiently protecting the probe pins from external impact or the like.

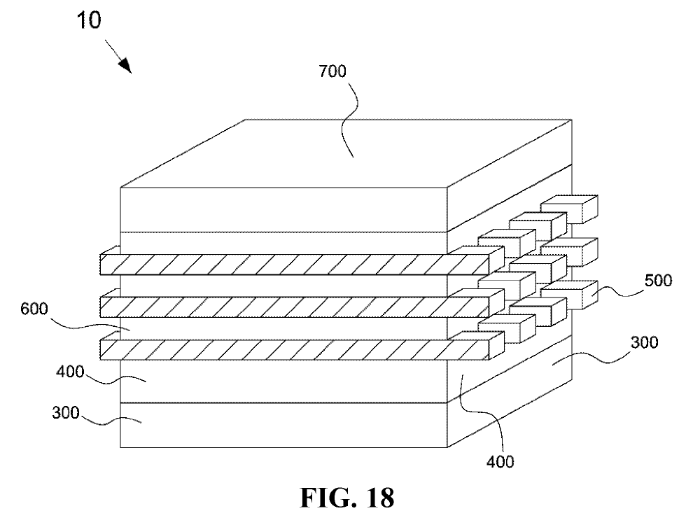

The sacrificial layer removal step (S80) is a step of removing the elastic sacrificial layer (410). However, referring to FIG. 18, this is a step of removing all sacrificial layers formed in addition to the elastic sacrificial layer (410), and when only the elastic sacrificial layer (410) is present as the sacrificial layer, only the elastic sacrificial layer (410) may be removed.

Therefore, the sacrificial layer removal step (S80) is a step of removing all of the elastic sacrificial layer (410), the substrate sacrificial layer (200), the first sacrificial layer (310), and the second sacrificial layer (710). The sacrificial layer removal step (S80) may utilize various methods capable of removing sacrificial layers, and a method such as etching may be used.

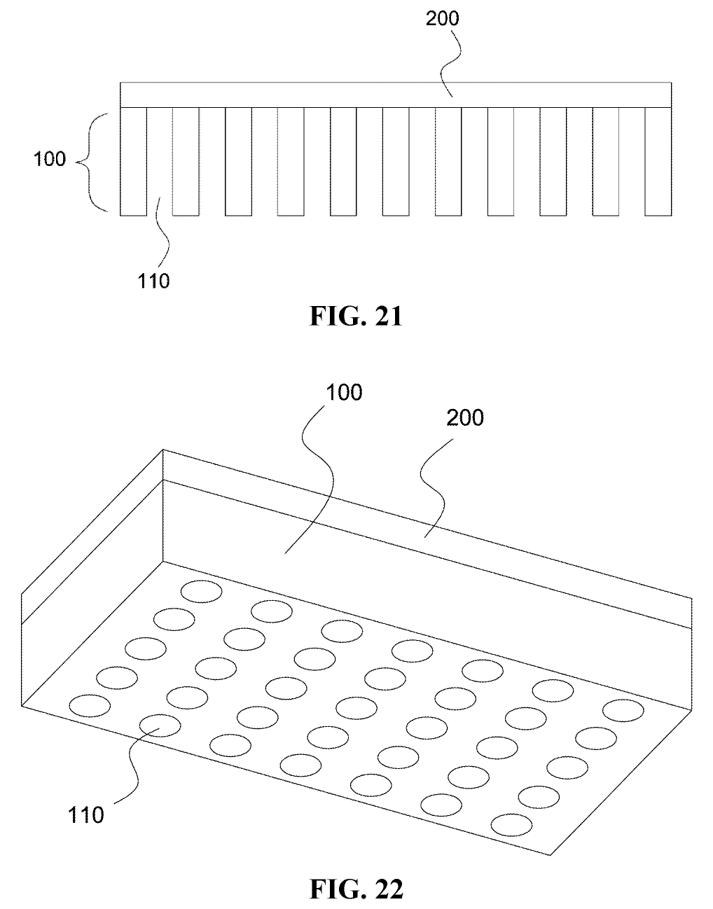

Meanwhile, referring to FIGS. 21 and 22, before or after the first elastic layer forming step (S20), a cavity forming step of forming one or more cavities (110) on the lower surface of the substrate may be further included. However, it is preferable that the cavity forming step (S30) be performed after the substrate sacrificial layer forming step, but when a substrate sacrificial layer or an elastic layer can be formed on the substrate after forming the cavities (110) in the substrate (100), the cavity forming step (S30) may be performed first.

FIG. 21 is a sectional view illustrating that the cavities (110) are formed in the substrate (100), and FIG. 22 is a perspective view looking up at the substrate (100) in which the cavities (110) are formed from below. In this manner, one or more cavities (110) may be formed, and cavities (110) arranged in various manners other than a grid shape may be formed. At this time, the cavities (110) may be formed by using a laser hole processing method, and a method of physically forming the cavities may also be used.

However, the laser hole processing method is preferable because the physical method has a problem in that foreign substances are generated.

Meanwhile, the cavities (110) formed in this manner may be used to remove the substrate sacrificial layer (200) in the sacrificial layer removal step (S80). When a solution capable of removing the substrate sacrificial layer (200) is introduced into the cavities (110) to dissolve the substrate sacrificial layer (200), the substrate (100) may be separated, and the probe head (10) stacked and formed on the substrate (100) may be secured.

Even if the cavities (110) are not formed, a solution capable of removing the substrate sacrificial layer (200) may be brought into contact through a portion where the substrate sacrificial layer (200) is exposed on a side surface, or the substrate may be physically detached, but when the cavities (110) are formed, the contact area of the solution for removing the substrate sacrificial layer (200) may be maximized, and damage to the probe head (10) that may occur while physically detaching the substrate (100) may be prevented.

The spatial converter (900) coupling step is a step of coupling the probe head (10) and the spatial converter (900) after the sacrificial layer removal step (S80), and the spatial converter (900) is provided to include, on one surface thereof, a plurality of spatial converter electrodes (910) connected to the other ends of the first probe pins (500). The spatial converter (900) may perform a pitch conversion function in that the pitch of the spatial converter electrodes (910) on a surface opposite to a surface contacting the first probe pins (500) is formed differently.

Accordingly, when the spatial converter (900) coupling step is provided in this manner, the probe pins formed at fine intervals at the other ends of the probe head (10) are connected to the spatial converter (900) so that they can be connected to each other by compensating for a difference between terminals on inspection equipment and the spacing between the probe pins.

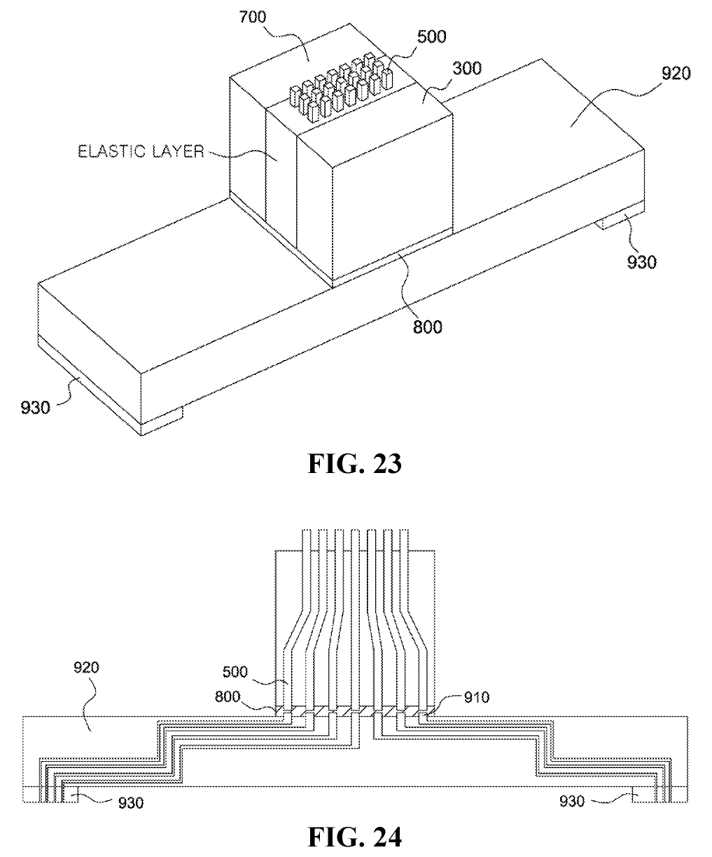

Referring to FIGS. 23 and 24, the spatial converter (900) may be formed to include configurations such as the spatial converter electrode (910), a body portion (920), and a connection portion (930), and the spatial converter electrode (910) is a configuration exposed on the upper portion of the spatial converter (900) to be electrically connected by contacting the probe pins of the probe head (10), and the body portion is a configuration in which the spatial converter electrode (910) is wired and electrically connected so as to be finally connected to other devices such as inspection equipment through the connection portion (930).

The spatial converter (900) having such a configuration may be characterized in that an anisotropic conductive film (800) is provided on a surface where the other ends of the first probe pins (500) and the spatial converter (900) are in contact, so that the first probe pins (500) and the plurality of spatial converter electrodes (910) provided in the spatial converter (900) are electrically connected.

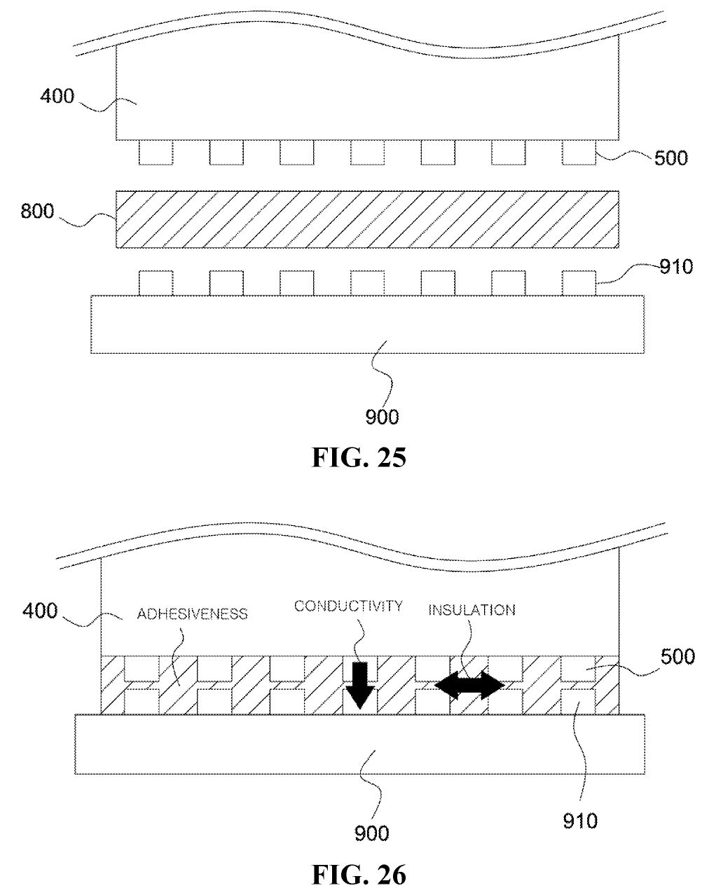

FIGS. 25 and 26 are views illustrating the spatial converter (900) coupling step, and illustrate a portion in which the first probe pins (500) of the probe head (10) and the spatial converter electrodes (910) of the spatial converter (900) are coupled with the anisotropic conductive film (800) interposed therebetween.

Referring thereto, the spatial converter (900) coupling step is performed in a manner in which the anisotropic conductive film (800) (Anisotropic Conductive Film) (ACF) is positioned between the other ends of the first probe pins (500) of the probe head (10) and the spatial converter (900) and then pressed, and when pressed, the configurations on both sides connected with the anisotropic conductive film (800) interposed therebetween allow electricity to mutually flow therethrough.

Meanwhile, the anisotropic conductive film (800) is formed to include an adhesive material and conductive particles. At this time, the conductive particles are as fine as about 3 to 15 μm in diameter, occupy about 0.5 to 5% of the total volume of the anisotropic conductive film (800), and are formed by coating polymer particles with electrically conductive metal materials such as Au, Ni, and Pd.

In addition, as the adhesive material, thermoplastic materials such as styrene butadiene and polyvinyl butylene, and thermosetting materials such as epoxy resin, polyurethane, and acrylic resin may be used.

FIG. 25 is a view illustrating that the anisotropic conductive film (800) is positioned between the other ends of the first probe pins (500) of the probe head (10) and the spatial converter (900), and FIG. 26 illustrates that the other ends of the first probe pins (500) of the probe head (10) and the spatial converter (900) are pressed with the anisotropic conductive film (800) interposed therebetween so that the spatial converter (900) coupling step is performed.

When pressed in this manner, electricity flows in a vertical direction between the first probe pins (500) and the spatial converter electrodes (910), which is the pressing direction, so as to have conductivity, and in a direction perpendicular to the pressing direction, insulation is provided so that electricity does not flow.

In addition, in the remaining portions where the first probe pins (500) and the spatial converter electrodes (910) are not in contact, they may be adhered to each other so as to have adhesiveness.

The spatial converter (900) coupling step is described on the basis that it is performed after the sacrificial layer removal step (S80), but may also be performed in a state in which the sacrificial layer removal step (S80) is not performed.

When it is performed in a state in which the sacrificial layer is not removed, pressure is applied only from the protruding spatial converter electrodes (910) toward the first probe pins (500). Even in this case, if the first probe pins (500) and the spatial converter electrodes (910) are vertically aligned without being misaligned, conductivity may be obtained in the vertical direction by the pressure applied from the spatial converter electrodes (910), and since the first probe pins (500) are surrounded by the elastic layer, they are insulated by the elastic layer and thus electricity still does not flow in the horizontal direction and insulation may be maintained.

However, it is preferable that the spatial converter (900) coupling step be performed after the sacrificial layer removal step (S80) because the first probe pins (500) and the spatial converter electrodes (910) can apply pressure to each other with the anisotropic conductive film (800) interposed therebetween.

When the probe pins of the probe head (10) and the spatial converter electrodes (910) of the spatial converter (900) are coupled by providing the anisotropic conductive film (800) in this manner, the process of coupling the spatial converter (900) may be simplified, and electrical connection may also be easily performed through the characteristics of the anisotropic conductive film (800).

Meanwhile, the above-described steps include a step of forming a sacrificial layer at one end or both ends, and the one end and the other end are portions connected to inspection equipment or an inspection target of the probe pins, and are for causing one of them to protrude or both of them to protrude. Although it is advantageous for both to protrude in contacting inspection equipment or an inspection target, it is also possible to manufacture the probe head (10) in a state in which one end does not protrude so that interference or contact does not occur between pins depending on the situation, and it is also possible that both ends do not protrude. However, when the spatial converter coupling step (S90) is further included, as described above, it is preferable that the probe pin portion of the probe head (10) connected to the spatial converter (900) protrude because it is easy for the spatial converter electrodes (910) to apply pressure with the anisotropic conductive film (800) interposed therebetween, and thus the probe pins are provided to protrude by forming sacrificial layers and removing the sacrificial layers.

The preferred embodiments described above are disclosed merely for illustrative purposes. Those skilled in the art will understand that various modifications, alterations, and additions can be made within the scope and spirit of the present invention, and such variations should be considered to fall within the scope of the claims.

Those skilled in the art may apply substitutions, variations, or modifications without departing from the technical spirit of the invention. Therefore, the present invention is not limited to the embodiments and drawings described above.

Although the exemplary system and method are described as a sequence of steps or blocks based on a flowchart, the invention is not limited to the sequence of these steps, and some steps may occur in different orders or simultaneously. Also, those skilled in the art will understand that additional steps may be included or that one or more steps may be omitted without departing from the scope of the invention.

### INDUSTRIAL APPLICABILITY

According to the present invention, it is possible to manufacture a probe head having a fine pitch between probe pins.

It is also possible to provide a probe head capable of inspecting multiple devices simultaneously.

Furthermore, the present invention provides a method for manufacturing a probe head in which the shape of the probe pins can be freely formed.

Additionally, the probe head and the spatial converter can be easily coupled by an anisotropic conductive film, and insulation can be secured.

1. A method for manufacturing a probe head, comprising:
a first elastic layer forming step of forming a first elastic layer;
a first pin forming step of forming one or more first probe pins on an upper surface of the first elastic layer; and
a second elastic layer stacking step of forming a second elastic layer over the first elastic layer on which the first probe pins are formed.

2. The method of claim 1, further comprising:
a second pin forming step of forming one or more second probe pins on an upper surface of the second elastic layer.

3. The method of claim 1, further comprising:
a layer stacking step of repeatedly performing the first pin forming step and the second elastic layer stacking step a predetermined number of times to stack layers composed of pin layers and elastic layers.

4. The method of claim 1, wherein the first pin forming step comprises:
forming the first probe pins in a manner such that they are arranged in parallel on a planar surface of an upper side of the first elastic layer.

5. The method of claim 1, wherein the first pin forming step comprises:
configuring the first probe pins such that a second spacing between other ends is greater than a first spacing between one ends, and
forming the first probe pins in a shape in which the one ends and the other ends are connected.

6. The method of claim 1, wherein the first pin forming step comprises:
forming one end and an other end of the first probe pin in a rod shape, and providing a shock-absorbing structure in a center thereof.

7. The method of claim 1, wherein the first elastic layer forming step and the second elastic layer stacking step comprise:
forming an elastic sacrificial layer at both ends of the first probe pins.

8. The method of claim 1, further comprising:
a first photoresist forming step, performed before the first elastic layer forming step, of forming a first photoresist including a first sacrificial layer at both ends of the first probe pins; and
a second photoresist forming step, performed after the second elastic layer stacking step, of forming a second photoresist including a second sacrificial layer at both ends of the first probe pins.

9. The method of claim 7, further comprising:
a sacrificial layer removal step of removing the elastic sacrificial layer, the first sacrificial layer, and the second sacrificial layer.

10. The method of claim 1, wherein the first elastic layer forming step is performed on an upper surface of a substrate, and
further comprising a cavity forming step, performed before or after the first elastic layer forming step, of forming one or more cavities on a lower surface of the substrate.

11. The method of claim 9, further comprising:
a spatial converter coupling step, performed after the sacrificial layer removal step, of coupling the probe head and a spatial converter, and
wherein the spatial converter includes, on one surface of the spatial converter, a plurality of spatial converter electrodes connected to the other ends of the first probe pins.

12. The method of claim 11, wherein:
the spatial converter is provided with an anisotropic conductive film on a surface where the other ends of the first probe pins and the spatial converter are in contact, such that the first probe pins and the plurality of spatial converter electrodes provided in the spatial converter are electrically connected.

13. The method of claim 8, further comprising:
a sacrificial layer removal step of removing the elastic sacrificial layer, the first sacrificial layer, and the second sacrificial layer.

14. The method of claim 13, further comprising:
a spatial converter coupling step, performed after the sacrificial layer removal step, of coupling the probe head and a spatial converter, and
wherein the spatial converter includes, on one surface of the spatial converter, a plurality of spatial converter electrodes connected to the other ends of the first probe pins.

15. The method of claim 14, wherein:
the spatial converter is provided with an anisotropic conductive film on a surface where the other ends of the first probe pins and the spatial converter are in contact, such that the first probe pins and the plurality of spatial converter electrodes provided in the spatial converter are electrically connected.
